(19) United States
(12) Patent Application Publication
(10) Pub. No.: US 2025/0324657 A1
(43) Pub. Date: Oct. 16, 2025

(54) TRANSISTOR AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US); Randy L. Yach, Phoenix, AZ (US)

(73) Assignee: Microchip Technology Incorporated, Chandler, AZ (US)

(21) Appl. No.: 18/924,026

(22) Filed: Oct. 23, 2024

Related U.S. Application Data
(60) Provisional application No. 63/634,279, filed on Apr. 15, 2024.

(51) Int. Cl. H01L 29/78; H01L 29/66

(52) U.S. Cl. CPC H10D 30/66; H10D 30/0291; H10D 30/051

(57) ABSTRACT

A transistor having a drain layer formed within a substrate. A drift layer formed over the drain layer, the drift layer having a recessed portion and a protruding portion with a tee-shaped portion. A well layer formed over the recessed portion of the drift layer. A body layer formed over a first portion of the well layer. A source layer formed over a second portion of the well layer. A JFET layer formed within the tee-shaped portion of the drift layer. An insulating layer formed over a portion of the source layer, over a fourth portion of the well layer along the sides of the protruding portion of the drift layer, and over the tee-shaped portion of the drift layer. A gate electrode formed over the insulating layer.

### CROSS-REFERENCE TO RELATED APPLICATION

The present application claims priority to U.S. Provisional Patent Application No. 63/634,279, filed on Apr. 15, 2024, the contents of which are hereby incorporated by reference in their entirety.

### TECHNICAL FIELD

The present disclosure relates to metal oxide semiconductor field-effect transistors (MOSFETs), and more specifically to high power MOSFETs and methods for manufacturing same to increase the amount current in a smaller die size of the MOSFET.

### SUMMARY

According to an aspect of one or more examples, there is provided a transistor that may include a substrate, a drain layer formed within the substrate, a drift layer formed over the drain layer, the drift layer having a recessed portion and a protruding portion with a tee-shaped portion, a well layer formed over the recessed portion of the drift layer and along sides of the protruding portion of the drift layer, a body layer formed over a first portion of the well layer, a source layer formed over a second portion of the well layer, the source layer extends into a third portion of the well layer, a JFET layer formed within the tee-shaped portion of the drift layer, an insulating layer formed over a portion of the source layer, over a fourth portion of the well layer along the sides of the protruding portion of the drift layer, and over the tee-shaped portion of the drift layer, and a gate electrode formed over the insulating layer. The substrate may comprise bulk gallium nitride, diamond, silicon carbide, aluminum nitride, or silicon. The drain layer may comprise a first concentration of a first type dopant. The drift layer may comprise a second concentration of the first type dopant, the first concentration may be greater than the second concentration. The well layer may comprise a third concentration of a second type dopant. The source layer may comprise a fourth concentration of the first type dopant. The JFET layer may comprise a fifth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

According to an aspect of one or more examples, there is provided a method of manufacturing a transistor that may include providing a substrate, forming a drain layer within the substrate, forming a drift layer over the drain layer, the drift layer having a recessed portion and a protruding portion with a tee-shaped portion, forming a well layer over the recessed portion of the drift layer and along sides of the protruding portion of the drift layer, forming a body layer over a first portion of the well layer, forming a source layer over a second portion of the well layer, the source layer extends into a third portion of the well layer, forming a JFET layer within the tee-shaped portion of the drift layer, forming an insulating layer over a portion of the source layer, over a fourth portion of the well layer along the sides of the protruding portion of the drift layer, and over the tee-shaped portion of the drift layer, and forming a gate electrode over the insulating layer. The substrate may comprise bulk gallium nitride, diamond, silicon carbide, aluminum nitride, or silicon. The drain layer may comprise a first concentration of a first type dopant. The drift layer may comprise a second concentration of the first type dopant, the first concentration may be greater than the second concentration. The well layer may comprise a third concentration of a second type dopant. The source layer may comprise a fourth concentration of the first type dopant. The JFET layer may comprise a fifth concentration of the first type dopant. The insulating layer may comprise polysilicon, oxide or a mixture of polysilicon and oxide. The first type dopant may comprise an n-type dopant and the second type dopant may comprise a p-type dopant. The first type dopant may comprise a p-type dopant and the second type dopant may comprise an n-type dopant.

### BRIEF DESCRIPTION OF DRAWINGS

FIG. 1 is a cross sectional view of a transistor according to one or more examples;

FIGS. 2A through 2F show a method of manufacturing a transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

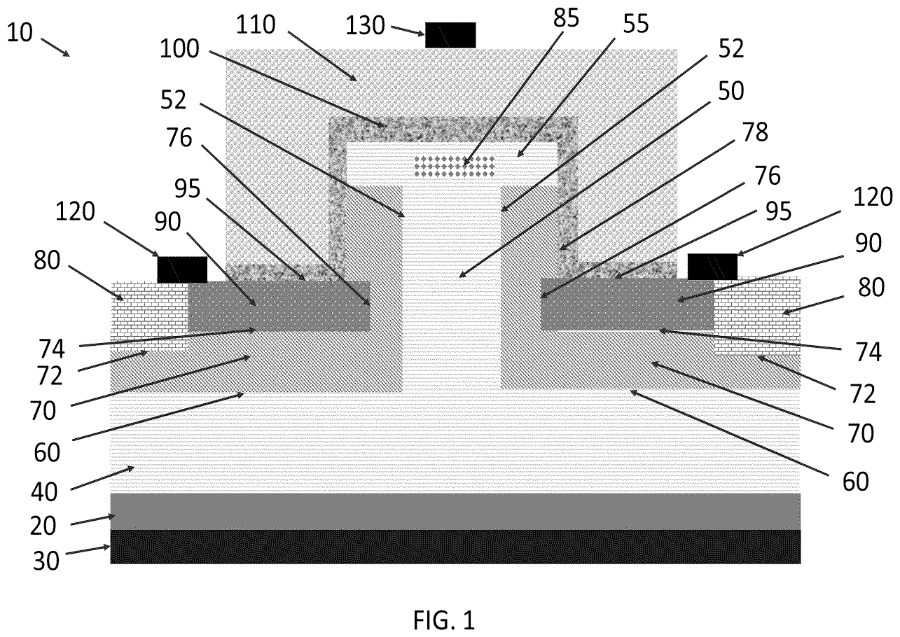

FIG. 1 is a cross sectional view of a transistor according to one or more examples. As shown in FIG. 1, the transistor 10 may have a substrate 20. The substrate 20 may comprise bulk gallium nitride, diamond, silicon carbide, aluminum nitride, or silicon. In FIG. 1, the example transistor 10 may include a drain layer 30 formed within the substrate 20. The drain layer 30 may have a first concentration of a first dopant type. The drain layer 30 may be doped so as to have a resistivity of less than 25 milliohm-cm. In FIG. 1, the example transistor 10 may include a drift layer 40 that may have a second concentration of the first type dopant and may be formed over the drain layer 30. The first concentration of first type dopant in the drain layer 30 may be greater than the second concentration of first type dopant in the drift layer 40. The drift layer 40 may comprise bulk gallium nitride, diamond, silicon carbide, aluminum nitride, or silicon. The drift layer 40 may have a protruding portion 50, a tee-shaped portion 55 and a recessed portion 60. In FIG. 1, the example transistor 10 may include a well layer 70 formed within the recessed portion 60 of the drift layer 40 and along sides 52 of the protruding portion 50 of the drift layer 40. The well layer 70 may have a third concentration of a second type dopant. In FIG. 1, the example transistor 10 may include a body layer 80 (this may be a body connection, a body extension or even a well connection) formed over a first portion 72 of the well layer 70. In FIG. 1, the example transistor 10 may include a source layer 90 formed over a second portion 74 of the well layer 70. The source layer 90 may extend into a third portion 76 of the well layer 70. The source layer 90 may comprise a fourth concentration of the first type dopant. A portion of the source layer 90 may be adjacent to the body layer 80. In FIG. 1, the example transistor 10 may include a source contact 120 formed over the source layer 90 and the body layer 80. In FIG. 1, the example transistor 10 may include a JFET layer 85 formed within the tee-shaped portion 55 of the drift layer 40. The JFET layer 85 may comprise a fifth concentration of the first type dopant. In FIG. 1, the example transistor 10 may include an insulating layer 100 formed over a portion 95 of the source layer 90, over a fourth portion 78 of the well layer 70 along the sides 52 of the drift layer 40, and over the tee-shaped portion 55 of the drift layer 40. The insulating layer 100 may comprise polysilicon, oxide or a mixture of polysilicon and oxide or any other insulating material. In FIG. 1, the example transistor 10 may include a gate electrode 110 formed over the insulating layer 100. In FIG. 1, the example transistor 10 may include a gate contact 130 formed over the gate electrode 110. In operation, the transistor 10 of the present invention may allow for the flow of charged particles from the source layer 90 through the tee-shaped portion 55 of the drift layer 40, through the protruding portion 50 of the drift layer 40 to the drain layer 30.

In the example transistor 10 of FIG. 1, the first type dopant may be an n-type dopant with the second type dopant being a p-type dopant. Alternatively, the first type dopant may be a p-type dopant with the second type dopant being an n-type dopant.

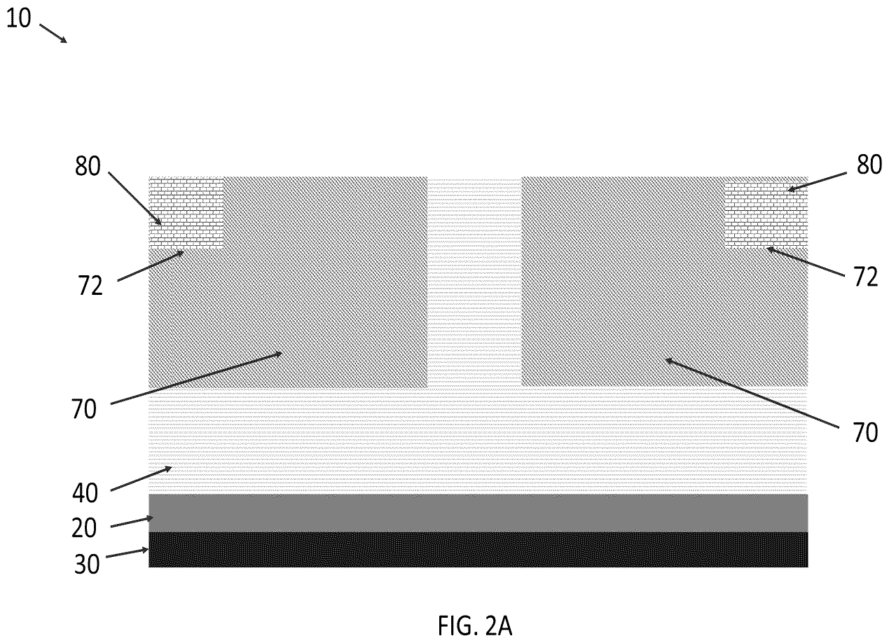

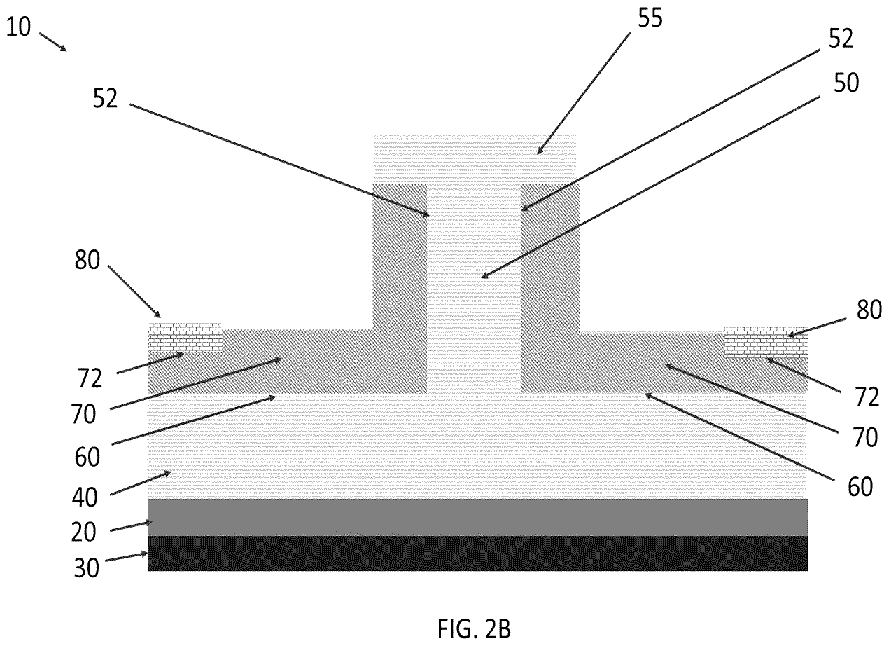

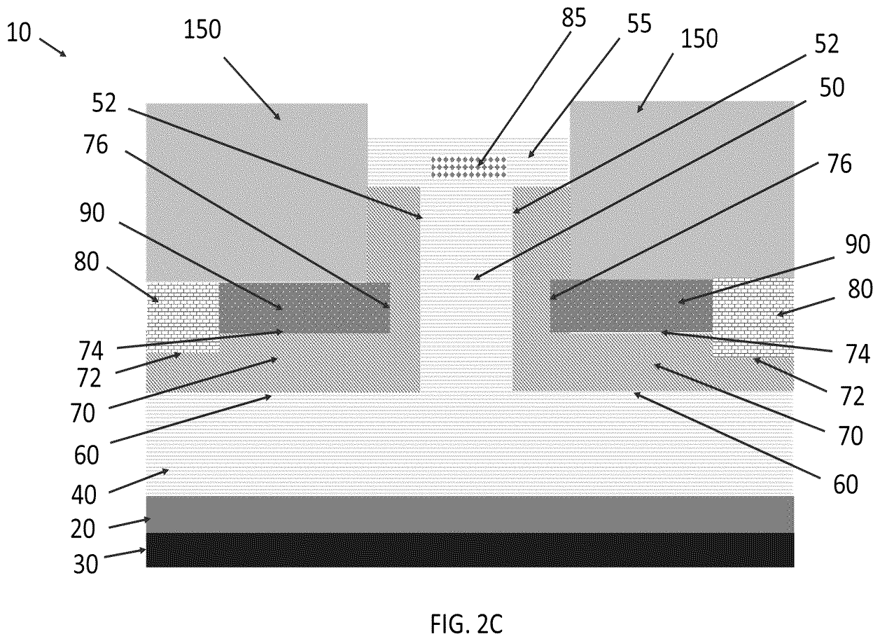

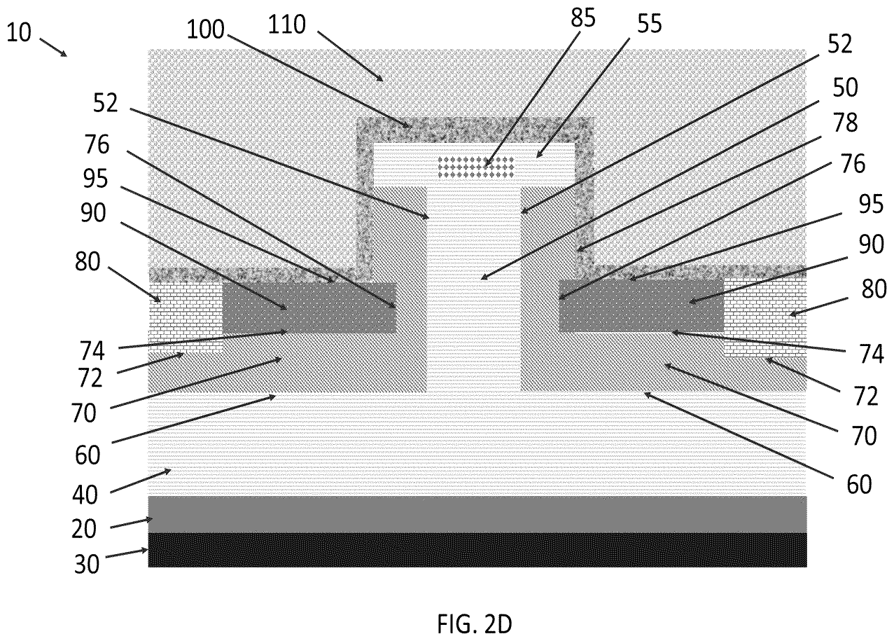

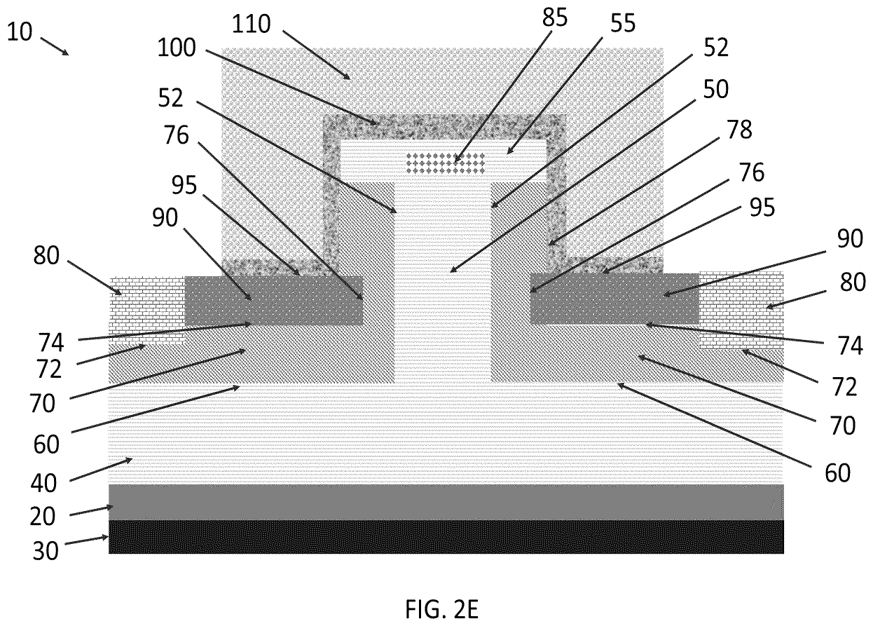

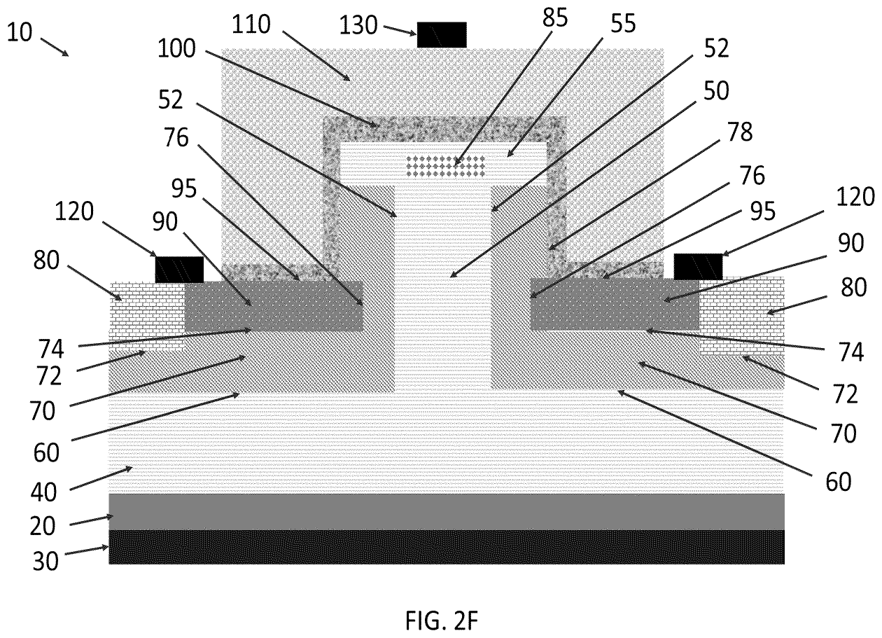

FIGS. 2A-2F show a method of manufacturing a transistor according to one or more examples. Although the example method shown in FIGS. 2A-2F include steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A is a cross sectional view of some of the steps in a method of manufacturing a transistor 10 according to one or more examples. In FIG. 2A, the example method may include providing a substrate 20. The substrate 20 may comprise bulk gallium nitride, diamond, silicon carbide, sapphire, aluminum nitride, or silicon. In FIG. 2A, the example method may include forming a drain layer 30 within the substrate 20. The drain layer 30 may have a first concentration of a first dopant type. The drain layer 30 may be doped so as to have a resistivity of less than 25 milliohm-cm. In FIG. 2A, the example method may include forming a drift layer 40 over the drain layer 30. The drift layer 40 that may have a second concentration of the first type dopant. The first concentration of first type dopant in the drain layer 30 may be greater than the second concentration of first type dopant in the drift layer 40. The drift layer 40 may comprise bulk gallium nitride, diamond, silicon carbide, aluminum nitride, or silicon. In FIG. 2A, the example method may include implanting a well layer 70 within the drift layer 40. The well layer 70 may have a third concentration of a second type dopant. In FIG. 2A, the example method may include implanting a body layer 80 (this may be a body connection, a body extension or even a well connection) over a first portion 72 of the well layer 70.

FIG. 2B is a cross sectional view of some of the steps in a method of manufacturing a transistor 10 according to one or more examples. In FIG. 2B, the example method may include forming a recessed portion 60 into the drift layer 40, forming a protruding portion 50 into the drift layer 40 and forming a tee-shaped portion 55 into the drift layer wherein the well layer 70 may remain over the recessed portion 60 of the drift layer 40 and along sides 52 of the protruding portion 50 of the drift layer 40.

FIG. 2C is a cross sectional view of some of the steps in a method of manufacturing a transistor 10 according to one or more examples. In FIG. 2C, the example method may include implanting a source layer 90 over a second portion 74 of the well layer 70. The source layer 90 may extend into a third portion 76 of the well layer 70. The source layer 90 may comprise a fourth concentration of the first type dopant. A portion of the source layer 90 may be adjacent to the body layer 80. In FIG. 2C, the example method may include a spacer 150 over the source layer 90 and the body layer 80. In FIG. 2C, the example method may include implanting a JFET layer 85 into the tee-shaped 55 portion of the drift layer 40. The JFET layer 85 may comprise a fifth concentration of the first type dopant.

FIG. 2D is a cross sectional view of some of the steps in a method of manufacturing a transistor according to one or more examples. In FIG. 2D, the example method may include removing the spacer 150 of FIG. 2C. In FIG. 2D, the example method may include forming an insulating layer 100 over the body layer 80, over a portion 95 of the source layer 90, over a fourth portion 78 of the well layer 70 along the sides 52 of the drift layer 40, and over the tee-shaped portion 55 of the drift layer 40. The insulating layer 100 may be polysilicon, oxide or a mixture of polysilicon and oxide or any other insulating material. In FIG. 2D, the example method may include forming a gate electrode 110 over the insulating layer 100.

FIG. 2E is a cross sectional view of some of the steps in a method of manufacturing a transistor according to one or more examples. In FIG. 2E, the example method may include patterning the insulating layer 100 such that the insulating layer 100 may be over a portion 95 of the source layer 90, over a fourth portion 78 of the well layer 70 along the sides 52 of the drift layer 40, and over the tee-shaped portion 55 of the drift layer 40. The gate electrode 110 may be patterned such that the gate electrode 110 may be over the patterned insulating layer 100.

FIG. 2F is a cross sectional view of some of the steps in a method of manufacturing a transistor 10 according to one or more examples. In FIG. 2F, the example method may include forming a gate contact 130 over the gate electrode 110. The gate contact 130 may be made from a metal, polysilicon, or other suitable material. In FIG. 2F, the example method may include forming a source contact 120 over the source layer 90 and the body layer 80. The source contact 120 may be made from a metal, polysilicon, or other suitable material. In operation, the transistor 10 of the present invention may allow for the flow of charged particles from the source layer 90 through the tee-shaped portion 55 of the drift layer 40, through the protruding portion 50 of the drift layer 40 to the drain layer 30.

In the example transistor 10 of FIGS. 2A-2F, the first type dopant may be an n-type dopant with the second type dopant being a p-type dopant. Alternatively, the first type dopant may be a p-type dopant with the second type dopant being an n-type dopant.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A transistor comprising:
a substrate;
a drain layer formed within the substrate;
a drift layer formed over the drain layer, the drift layer having a recessed portion and a protruding portion with a tee-shaped portion;
a well layer formed over the recessed portion of the drift layer and along sides of the protruding portion of the drift layer;
a body layer formed over a first portion of the well layer;
a source layer formed over a second portion of the well layer, the source layer extends into a third portion of the well layer;
a JFET layer formed within the tee-shaped portion of the drift layer;
an insulating layer formed over a portion of the source layer, over a fourth portion of the well layer along the sides of the protruding portion of the drift layer, and over the tee-shaped portion of the drift layer; and
a gate electrode formed over the insulating layer.

2. The transistor of claim 1, wherein the substrate comprises bulk gallium nitride, diamond, silicon carbide, aluminum nitride, or silicon.

3. The transistor of claim 1, wherein the drain layer comprises a first concentration of a first type dopant.

4. The transistor of claim 3, wherein the drift layer comprises a second concentration of the first type dopant, the first concentration is greater than the second concentration.

5. The transistor of claim 4, wherein the well layer comprises a third concentration of a second type dopant.

6. The transistor of claim 5, wherein the source layer comprises a fourth concentration of the first type dopant.

7. The transistor of claim 6, wherein the JFET layer comprises a fifth concentration of the first type dopant.

8. The transistor of claim 7, wherein the first type dopant comprises an n-type dopant and the second type dopant comprises a p-type dopant.

9. The transistor of claim 7, wherein the first type dopant comprises a p-type dopant and the second type dopant comprises an n-type dopant.

10. The transistor of claim 1, wherein the insulating layer comprises silicon nitride, silicon dioxide or a mixture of silicon nitride and silicon dioxide.

11. A method of manufacturing a transistor, the method comprising:
providing a substrate;
forming a drain layer within the substrate;
forming a drift layer over the drain layer, the drift layer having a recessed portion and a protruding portion with a tee-shaped portion;
forming a well layer over the recessed portion of the drift layer and along sides of the protruding portion of the drift layer;
forming a body layer over a first portion of the well layer;
forming a source layer over a second portion of the well layer, the source layer extends into a third portion of the well layer;
forming a JFET layer within the tee-shaped portion of the drift layer;
forming an insulating layer over a portion of the source layer, over a fourth portion of the well layer along the sides of the protruding portion of the drift layer, and over the tee-shaped portion of the drift layer; and
forming a gate electrode over the insulating layer.

12. The method for fabricating a transistor according to claim 11, wherein the substrate comprises bulk gallium nitride, diamond, silicon carbide, aluminum nitride, or silicon.

13. The method for fabricating a transistor according to claim 11, wherein the drain layer comprises a first concentration of the first type dopant.

14. The method for fabricating a transistor according to claim 13, wherein the drift layer comprises a second concentration of the first type dopant, the first concentration is greater than the second concentration.

15. The method for fabricating a transistor according to claim 14, wherein the well layer comprises a third concentration of a second type dopant.

16. The method for fabricating a transistor according to claim 15, wherein the source layer comprises a fourth concentration of the first type dopant.

17. The method for fabricating a transistor according to claim 16, wherein the JFET layer comprises a fifth concentration of the first type dopant.

18. The method for fabricating a transistor according to claim 17, wherein the first type dopant comprises an n-type dopant and the second type dopant comprises a p-type dopant.

19. The method for fabricating a transistor according to claim 17, wherein the first type dopant comprises a p-type dopant and the second type dopant comprises an n-type dopant.

20. The method for fabricating a transistor according to claim 11, wherein the insulating layer comprises silicon nitride, silicon dioxide or a mixture of silicon nitride and silicon dioxide.
